(19) United States
(12) Patent Application Publication
(10) Pub. No.: US 2007/0070604 A1
(43) Pub. Date: Mar. 29, 2007

(54) Cooling device and electronic apparatus having cooling device

(76) Inventors: Kentaro Tomioka, Sayama-shi (JP); Hiroshi Nishibayashi, Tokyo (JP)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/529,449

(22) Filed: Sep. 27, 2006

(30) Foreign Application Priority Data
Sep. 28, 2005 (JP) P2005-281717

(51) Int. Cl. H05K 7/20; F28F 7/00

(52) U.S. Cl. 361/696; 165/80.4; 361/722

(57) ABSTRACT

According to one embodiment, a cooling device includes: a first heat receiving portion that is configured to be thermally connected to a first heating element; a second heat receiving portion that is configured to be thermally connected to a second heating element having a greater heating value than the first heating element, the second heat receiving portion having a pump that pressurizes and feeds a liquid refrigerant; a heat radiation portion that radiates the heat received by the first and second heating elements; and a circulation passage that circulates a liquid refrigerant around the first heat receiving portion, the second heat receiving portion, and the heat radiation portion, wherein the second heat receiving portion is located at a position upstream with respect to the first heat receiving portion in a flow direction of the liquid refrigerant and downstream with respect to the heat radiation portion in the flow direction.

### CROSS-REFERENCE TO RELATED APPLICATIONS

This application is based upon and claims the benefit of priority from Japanese Patent Application No. 2005-281717, filed Sep. 28, 2005, the entire contents of which are incorporated herein by reference

### BACKGROUND

1. Field

One embodiment of the present invention relates to a cooling device of liquid cooling type for cooling a plurality of electronic parts that generate the heat, for example, and an electronic apparatus mounting the cooling device.

2. Description of the Related Art

The electronic parts such as a CPU and a VGA controller used for an electronic apparatus give off a rapidly increasing quantity of heat along with higher density packaging or higher function. As the measure against heat, a cooling module has been recently proposed in which a plurality of electronic parts are collectively cooled, employing a liquid refrigerant such as antifreeze fluid.

The conventional cooling module has a first heat receiving portion thermally connected to one electronic part, and a second heat receiving portion thermally connected to another electronic part. The first heat receiving portion and the second heat receiving portion are integrally formed within a metallic casing to adjoin each other.

The first heat receiving portion contains a pump for pressurizing and feeding the liquid refrigerant. The second heat receiving portion has a flow passage through which the liquid refrigerant flows, the downstream end of this flow passage being connected to a suction end of the pump.

With such cooling module, the liquid refrigerant firstly flows into the flow passage of the second heat receiving portion, and deprives the electronic parts of the heat conductive to the second heat receiving portion in the course of flowing on this flow passage. Then, the liquid refrigerant flows into the first heat receiving portion, deprives the electronic parts of the heat conductive to the first heat receiving portion while being pressurized by the pump, and is discharged out of the first heat receiving portion.

Consequently, one cooling module can absorb the heat liberated from a plurality of electronic parts, and cool the plurality of electronic parts at the same time.

With the cooling module as disclosed in the JP-A-2004-253435, the first heat receiving portion containing the pump is formed in larger size than the second heat receiving portion with the flow passage only. Therefore, to realize the efficient heat receiving and cooling capability, it is desirable that the relatively large electronic components such as a CPU likely having high temperatures are thermally connected to the first heat receiving portion, and the relatively small electronic parts having smaller heating value are thermally connected to the second heat receiving portion, as described in paragraph number 0062 of the JP-A-2004-253435.

However, since the liquid refrigerant flows from the second heat receiving portion to the first heat receiving portion, the temperature of the liquid refrigerant already rises by heat exchange with the second heat receiving portion, at the time when the liquid refrigerant reaches the first heat receiving portion.

In other words, the liquid refrigerant of low temperature can not be led to the electronic parts with the highest temperature, resulting in less temperature difference between the liquid refrigerant and the electronic parts. As a result, the electronic parts particularly having high temperatures can not be cooled efficiently.

Moreover, in the cooling module of JP-A-2004-253435, the first heat receiving portion and the second heat receiving portion have an integral structure. Therefore, there is nonconformance that the positional relationship between the first heat receiving portion and the second heat receiving portion is firmly settled, causing the degree of freedom in laying out the first and second heating elements to be lost.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary perspective view of an electronic apparatus according to a first embodiment of the present invention.

FIG. 2 is an exemplary cross-sectional view of the electronic apparatus according to the first embodiment of the invention.

FIG. 3 is an exemplary cross-sectional view of a first heat receiving portion thermally connected to a first heating element.

FIG. 4 is an exemplary cross-sectional view showing a state where a heat exchanger pump and a second heating element are thermally connected according to the first embodiment of the invention.

FIG. 5 is an exemplary perspective view of the heat exchanger pump showing a state where a casing main body and a heat receiving cover are separated from each other according to the first embodiment of the invention.

FIG. 6 is an exemplary plan view of the casing main body showing a state where an impeller is accommodated in a pump room in the first embodiment of the invention.

FIG. 7 is an exemplary perspective view of the casing main body according to the first embodiment of the invention.

FIG. 8 is an exemplary front view of a radiator making up a heat radiation portion in the first embodiment of the invention.

FIG. 9 is an exemplary cross-sectional view of the radiator showing the positional relationship between a radiator core and a reserve tank in the first embodiment of the invention.

FIG. 10 is an exemplary perspective view of an electronic apparatus according to a second embodiment of the invention.

FIG. 11 is an exemplary perspective view of the electronic apparatus according to the second embodiment of the invention.

FIG. 12 is an exemplary front view showing the positional relation between two radiators in the second embodiment of the invention.

FIG. 13 is an exemplary cross-sectional view of the radiator showing the positional relation between the radiator core and the reserve tank in a third embodiment of the invention.

FIG. 14 is an exemplary front view of the heat radiation portion according to a fourth embodiment of the invention.

FIG. 15 is an exemplary side view of the heat radiation portion according to the fourth embodiment of the invention.

### DETAILED DESCRIPTION

Various embodiments according to the invention will be described hereinafter with reference to the accompanying drawings. In general, according to one embodiment of the invention, a cooling device includes: a first heat receiving portion that is configured to be thermally connected to a first heating element; a second heat receiving portion that is configured to be thermally connected to a second heating element having a greater heating value than the first heating element, the second heat receiving portion having a pump that pressurizes and feeds a liquid refrigerant; a heat radiation portion that radiates the heat received by the first and second heating elements; and a circulation passage that circulates a liquid refrigerant around the first heat receiving portion, the second heat receiving portion, and the heat radiation portion, wherein the second heat receiving portion is located at a position upstream with respect to the first heat receiving portion in a flow direction of the liquid refrigerant and downstream with respect to the heat radiation portion in the flow direction. According to another embodiment of the invention, an electronic apparatus comprising: a housing that is configured to accommodating a first heating element and a second heating element having a greater heating value than the first heating element, the second heat receiving portion having a pump that pressurizes and feeds a liquid refrigerant; a cooling device that is accommodated within the housing, for cooling the first and second heating elements employing a liquid refrigerant; wherein the cooling device comprises: a first heat receiving portion that is configured to be thermally connected to the first heating element; a second heat receiving portion that is configured to be thermally connected to the second heating element; a heat radiation portion that radiates the heat of the first and second heating elements; and a circulation passage that circulates the liquid refrigerant around the first heat receiving portion, the second heat receiving portion, and the heat radiation portion, wherein the second heat receiving portion is located at a position upstream with respect to the first heat receiving portion in a flow direction of the liquid refrigerant and downstream with respect to the heat radiation portion in the flow direction.

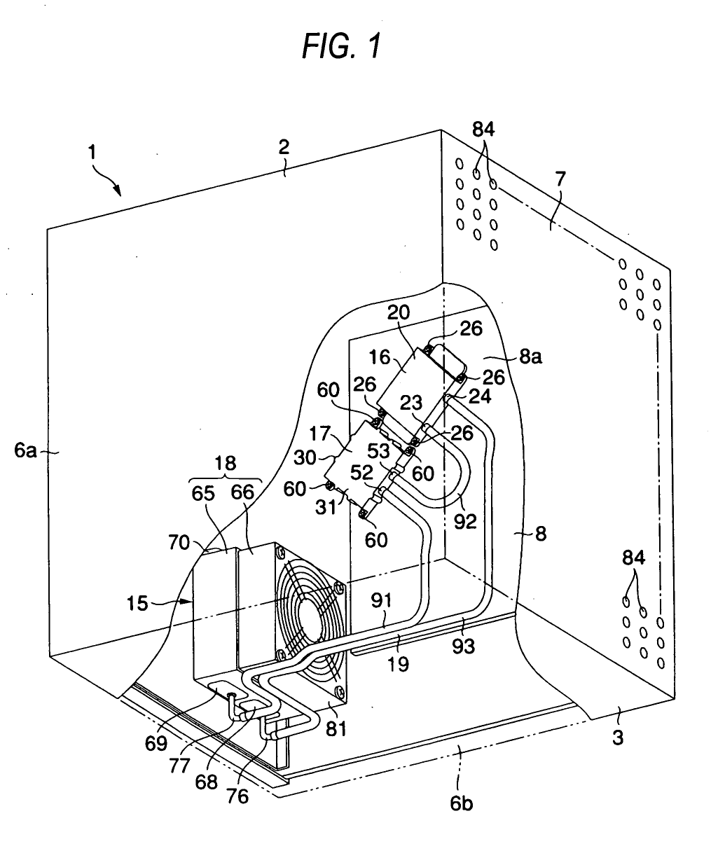

FIG. 1 shows a stationary computer 1 that is an example of an electronic apparatus. The computer 1 has a housing 2 placed on a roof plate of a desk, for example. The housing 2 is like a hollow box having a bottom wall 3, an upper wall 4, a front wall 5, the left and right side walls 6a, 6b, and a rear wall 7.

The housing 2 accommodates a printed circuit board 8. The printed circuit board 8 stands vertically along the depth direction of the housing 2 to be parallel to the side walls 6a and 6b.

The printed circuit board 8 has a first face 8a and a second face 8b located on the opposite side of the first face 8a. A first heating element 10 and a second heating element 11 are mounted on the first face 8a of the printed circuit board 8.

The first heating element 10 is a semiconductor package making up a VGA controller, for example. The second heating element 11 is a semiconductor package of BGA type making up a CPU, for example. The first and second heating elements 10 and 11 adjoin each other in the central par of the printed circuit board 8.

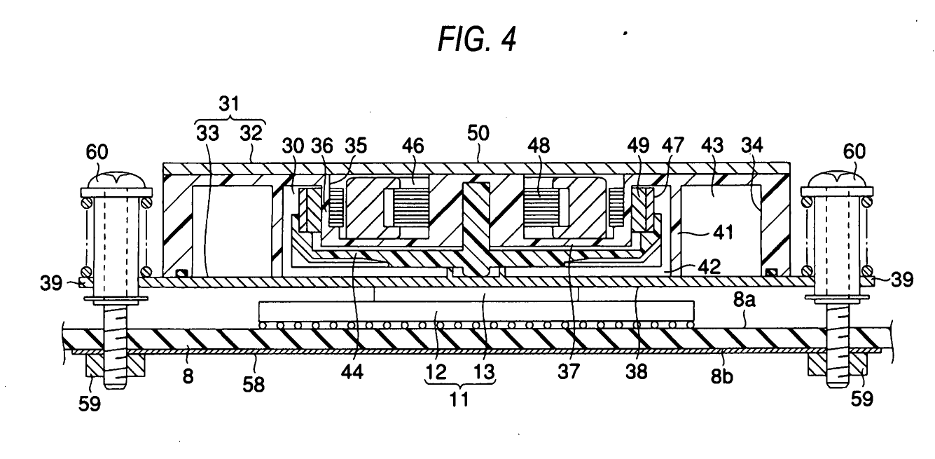

As shown in FIG. 4, the second heating element 11 has a base substrate 12 and an IC chip 13. The base substrate 12 is soldered onto the first face 8a of the printed circuit board 8. The IC chip 13 is packaged in the central part of the base substrate 12. The second heating element 11 has greater heating value during operation than the first heating element 10, along with the higher processing speed and multi-function of the IC chip 13. The first and second heating elements 10 and 11 require the cooling for keeping the stable operation.

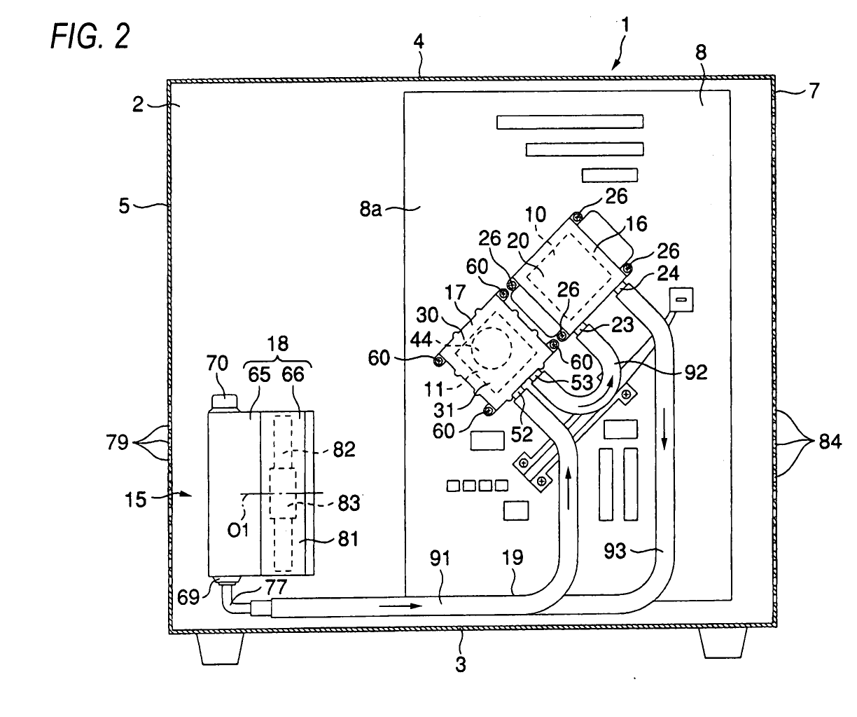

As shown in FIGS. 1 and 2, the housing 2 of the computer 1 mounts a cooling device 15 of liquid cooling type for cooling the first and second heating elements 10 and 11, using a liquid refrigerant such as water or antifreeze. The cooling device 15 comprises a first heat receiving portion 16, a second heat receiving portion 17, a heat radiation portion 18 and a circulation passage 19.

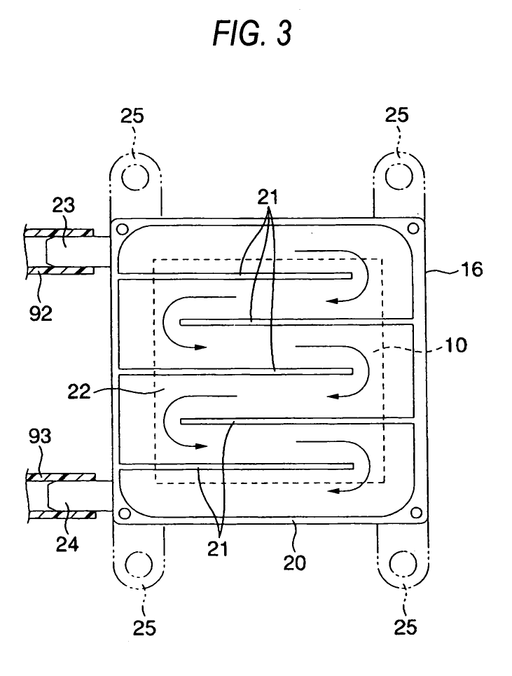

As shown in FIG. 3, the first heat receiving portion 16 has a heat receiving casing 20. The heat receiving casing 20 is an oblate rectangular box a size larger than the first heating element 10, and made of a metal material having high heat conductivity such as aluminum alloy.

A plurality of guide walls 21 are formed inside the heat receiving casing 20. The guide walls 21 define a refrigerant flow passage 22 through which the liquid refrigerant flows inside the heat receiving casing 20. The refrigerant flow passage 22 is bent in a serpentine manner.

The heat receiving casing 20 has a flow inlet 23 located at the upstream end of the refrigerant flow passage 22 and a flow outlet 24 located at the downstream end of the refrigerant flow passage 22. The flow inlet 23 and the flow outlet 24 project in the same direction from the side face of the heat receiving casing 20.

Moreover, the heat receiving casing 20 has four tongue pieces 25. The tongue pieces 25 jut out from four corner portions of the heat receiving casing 20 around the heat receiving casing 20, and are fixed by screws 26 in the printed circuit board 8. Thereby, the heat receiving casing 20 is held in the printed circuit board 8 in an attitude covering the first heating element 10 and thermally connected to the first heating element 10.

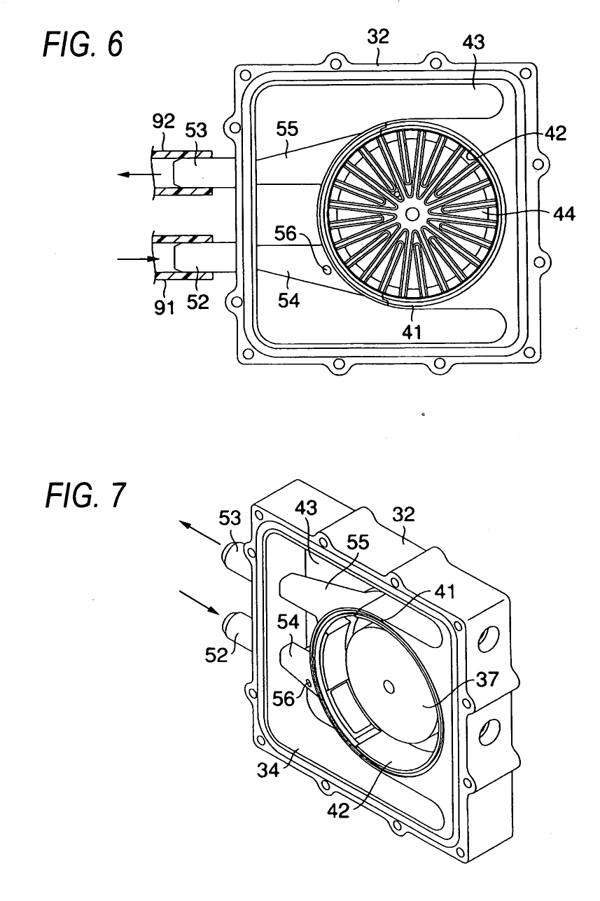

As shown in FIGS. 4 to 7, the second heat receiving portion 17 is separated from the first heat receiving portion 16 to be independent, and contains a heat exchanger pump 30. The heat exchanger pump 30 comprises a pump casing 31 serving as the heat receiving casing.

The pump casing 31 has a casing main body 32 and a heat receiving cover 33. The casing main body 32 is an oblate rectangular box a size larger than the second heating element 11, and made of synthetic resin having heat resistance, for example.

The casing main body 32 has a first concave portion 34 and a second concave portion 35. The first concave portion 34 and the second concave portion 35 are opened mutually oppositely along a thickness direction of the casing main body 32. The second concave portion 35 has a cylindrical peripheral wall 36 and a circular end wall 37 located at one end of the peripheral wall 36. The peripheral wall 36 and the end wall 37 are located inside the first concave portion 34.

The heat receiving cover 33 is made of a metal material having high heat conductivity, such as copper or aluminum. The heat receiving cover 33 is fixed in the casing main body 32 to close an open end of the first concave portion 34. The heat receiving cover 33 has a flat heating surface 38 exposed out of the pump casing 31. The tongue pieces 39 are formed at four corner portions of the heat receiving cover 33. The tongue pieces 39 jut out of the casing main body 32.

As shown in FIGS. 4 and 7, the casing main body 32 has a cylindrical peripheral wall 41. The peripheral wall 41 surrounds the peripheral wall 36 of the second concave portion 35 coaxially, with its lower end bonded to the heat receiving cover 33. The peripheral wall 41 partitions the inside of the first concave portion 34 into a pump room 42 and a reserve tank 43.

An impeller 44 is accommodated within the pump room 42. The impeller 44 is supported for free rotation between the end wall 37 of the second concave portion 35 and the heat receiving cover 33. The reserve tank 43 reserves the liquid refrigerant, and surrounds the pump room 42.

An oblate motor 46 for rotating the impeller 44 is incorporated into the casing main body 32. The oblate motor 46 has a rotor 47 and a stator 48. The rotor 47 is fixed coaxially around the outer periphery of the impeller 44, and located on the outer periphery of the pump room 42. A magnet 49 is fitted inside the rotor 47. The magnet 49 is rotated integrally with the rotor 47 and the impeller 44.

The stator 48 is accommodated in the second concave portion 35 of the casing main body 32. The stator 48 is located coaxially inside the magnet 49 of the rotor 47. The peripheral wall 36 of the second concave portion 35 is interposed between the stator 48 and the magnet 49. The open end of the second concave portion 35 is closed by a back plate 50 covering the stator 48.

The stator 48 is energized at the same time when the power of the computer 1 is turned on. With this energization, a rotating magnetic field arises in the circumferential direction of the stator 48, so that the magnet 49 of the rotor 47 is magnetically coupled with this magnetic field. As a result, a torque along the circumferential direction of the rotor 47 arises between the stator 48 and the magnet 49, and the impeller 44 is rotated.

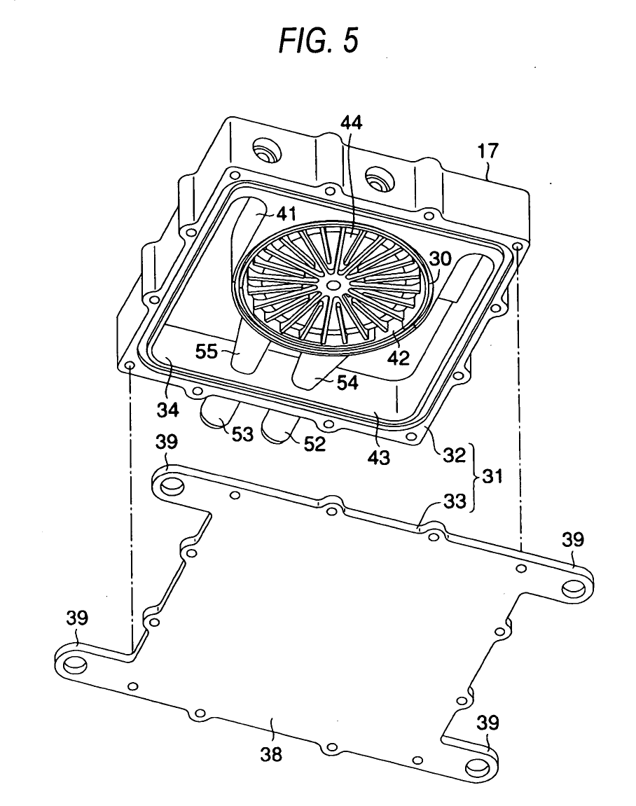

As shown in FIGS. 5 and 7, the casing main body 32 comprises a suction opening 52 sucking the liquid refrigerant and a discharge port 53 discharging the liquid refrigerant. The suction opening 52 and the discharge port 53 project in the same direction from the side face of the casing main body 32.

The suction opening 52 leads via a first connection passage 54 to the pump room 42. The discharge port 53 leads via a second connection passage 55 to the pump room 42. The first and second connection passages 54 and 55 traverse the inside of the reserve tank 43. The first connection passage 54 has a vent hole 56 for gas-liquid separation. The vent hole 56 is opened into the reserve tank 43, and always located below the level of liquid refrigerant reserved in the reserve tank 43.

As shown in FIG. 4, the second heat receiving portion 17 is attached on the printed circuit board 8 in an attitude where the heat receiving cover 33 of the heat exchanger pump 30 is faced with the second heating element 11. A metallic reinforcing plate 58 is superposed on the second plane 8b of the printed circuit board 8. The reinforcing plate 58 is opposed to the heat exchanger pump 30 across the printed circuit board 8 and has the nuts 59 at the positions corresponding to four tongue pieces 39 of the pump casing 31.

A screw 60 is inserted into the tongue piece 39 of the pump casing 31. The screw 60 is fastened through the printed circuit board 8 by the nut 59. By this screw, the second heat receiving portion 17 integral with the heat exchanger pump 30 is held in the printed circuit board 8 in an attitude covering the second heating element 11. As a result, a heating surface 38 of the heat receiving cover 33 is thermally connected to the IC chip 13 of the second heating element 11.

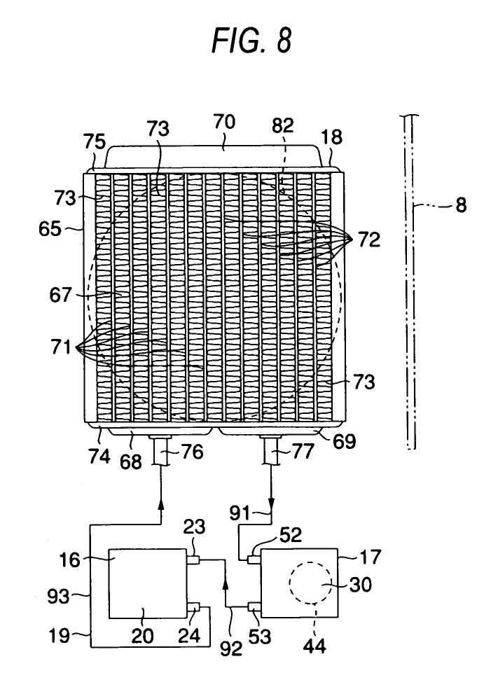

As shown in FIGS. 1 and 2, the heat radiation portion 18 of the cooling device 15 is installed on the bottom at the front end of the housing 2. The heat radiation portion 18 discharges the heat of the first and second heating elements 10 and 11, and comprises a radiator 65 and an axial flow fan 66. As shown in FIG. 8, the radiator 65 comprises a radiator core 67, an inflow tank 68, an outflow tank 69 and a reserve tank 70.

The radiator core 67 has a plurality of first water pipes 71 through which the liquid refrigerant flows, a plurality of second water pipes 72 through which the liquid refrigerant flows, and a plurality of fins 73. The first and second water pipes 71 and 72 are aligned with a spacing from each other, and stand along the height direction of the housing 2. The fins 73 are interposed between adjacent water pipes 71 and 72, and thermally connected to the water pipes 71 and 72. The lower ends of the first and second water pipes 71 and 72 are connected by a lower plate 74. Likewise, the upper ends of the first and second water pipes 71 and 72 are connected by an upper plate 75.

The inflow tank 68 and the outflow tank 69 are soldered to the lower face of the lower plate 74, and disposed in an array direction of the first and second water pipes 71 and 72. The inflow tank 68 has a size corresponding to an array area of the first water pipes 71, and is formed with a refrigerant inlet 76 in the central part of this inflow tank 68. The lower ends of the first water pipes 71 are opened into the inflow tank 68.

The outflow tank 69 has a size corresponding to an array area of the second water pipes 72, and is formed with a refrigerant outlet 77 in the central part of this outflow tank 69. The lower ends of the second water pipes 72 are opened into the outflow tank 69.

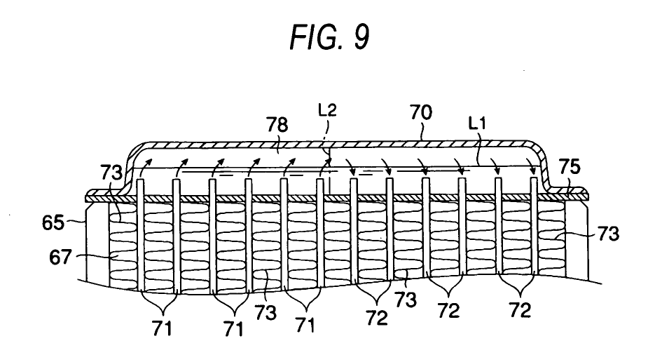

As shown in FIG. 9, the reserve tank 70 is soldered to the upper face of the upper plate 75. The reserve tank 70 has a size spreading over the array area of the first and second water pipes 71 and 72, and extends along the width direction of the radiator core 67. The upper ends of the first water pipes 71 and the upper ends of the second water pipes. 72 are opened into the reserve tank 70.

The liquid refrigerant is led through the refrigerant inlet 76 into the inflow tank 68 and flows into the lower ends of the first water pipes 71. The liquid refrigerant flows through the first water pipes 71 from down to up, and is discharged into the reserve tank 70. The liquid refrigerant discharged into the reserve tank 70 is temporarily reserved in the reserve tank 70, and flows into the upper ends of the second water pipe 72. The liquid refrigerant flows through the second water pipes 72 from up to down, and is discharged into the outflow tank 69.

As shown in FIG. 9, the upper ends of the first and second water pipes 71 and 72 are located below the level L1 of liquid refrigerant reserved in the reserve tank 70. An air reservoir 78 is formed between the upper face of the reserve tank 70 and the level L1 of liquid refrigerant.

Therefore, when the liquid refrigerant discharged from the first water pipes 71 into the reserve tank 70 contains gas components such as air bubbles, the gas components are separated from the liquid refrigerant in the course of flowing into the second water pipes 72, and released into the air reservoir 78.

Accordingly, the reserve tank 70 of the first embodiment also serves as gas-liquid separation means for separating the gas components from the liquid refrigerant led into the radiator 65.

In a layout of the inside of the housing 2, the radiator 65 may be installed in a transverse attitude so that the first and second water pipes 71 and 72 may lie horizontally. In this case, the radiator 65 is oriented so that the second water pipes 72 may be located under the first water pipes 71. Thereby, the ends of the second water pipes 72 opened into the reserve tank 70 are located below the level L2 of liquid refrigerant as indicated by the two-dot chain line in FIG. 9.

Therefore, even if the liquid refrigerant discharged from the first water pipes 71 into the reserve tank 70 contains air bubbles, the air bubbles are separated from the liquid refrigerant within the reserve tank 70.

The radiator 65 with the above constitution stands along the front wall 5 of the housing 2,and confronts a plurality of intake ports 79 opened in the front wall 5. In other words, the intake ports 79 are covered with the radiator 65 from inside the housing 2.

The axial flow fan 66 of the heat radiation portion 18 has a rectangular fan case 81, an impeller 82 accommodated within this fan case 81, and a motor 83 for rotating this impeller 82. The impeller 82 is supported within the fan case 81 in a transverse attitude where its rotational axial line O1 lies along the depth direction of the housing 2. The axial flow fan 66 is installed behind the radiator 65, and the impeller 82 is opposed to the intake ports 79 across the radiator 65.

If the impeller 82 is rotated, a negative pressure acts on the intake ports 79 of the housing 2, so that an outer air of the housing 2 is sucked into the intake ports 79. The sucked air becomes a cooling wind to pass through the radiator core 67, and is discharged into the inside of the housing 2. The cooling wind warmed by heat exchange with the radiator core 67 cools the printed circuit board 8 and the first and second heat receiving portions 16 and 17, and are exhausted through a plurality of exhaust holes 84 opened in the rear wall 7 of the housing 2 out of the housing 2.

As shown in FIGS. 1 and 2, the circulation passage 19 of the cooling device 15 circulates the liquid refrigerant and connects the first heat receiving portion 16, the second heat receiving portion 17 and the radiator 65 in series.

The circulation passage 19 has the first to third tubes 91, 92 and 93. The first to third tubes 91, 92 and 93 are made of flexible material such as rubber or synthetic resin.

The first tube 91 connects the refrigerant outlet 77 of the radiator 65 and the suction opening 52 of the heat exchanger pump 30. The second tube 92 connects the discharge port 53 of the heat exchanger pump 30 and the inflow port 23 of the first heat receiving portion 16. The third tube 93 connects the outflow port 24 of the first heat receiving portion 16 and the refrigerant inlet 76 of the radiator 65.

The liquid refrigerant flowing out of the refrigerant outlet 77 of the radiator 65 is led via the second heat receiving portion 17 into the first heat receiving portion 16, and then returned to the refrigerant inlet 76 of the radiator 65. Hence, the second heat receiving portion 17 is located upstream of the first heat receiving portion 16 along the flow direction of the liquid refrigerant, and downstream of the radiator 65 along the flow direction of the liquid refrigerant.

Next, the operation of the cooling device 15 will be described below.

The first heating element 10 and the second heating element 11 are heated during the use of the computer 1. The heat generated by the first heating element 10 is conductive to the heat receiving casing 20 of the first heat receiving portion 16. Since the refrigerant flow passage 22 within the heat receiving casing 20 is filled with the liquid refrigerant, this liquid refrigerant absorbs the heat of the first heating element 10 conducting to the heat receiving casing 20.

On the other hand, the heat generated by the second heating element 11 conducts through the heating surface 38 to the pump casing 31 of the heat exchanger pump 30. Since the pump room 42 within the pump casing 31 and the reserve tank 43 are filled with the liquid refrigerant, this liquid refrigerant absorbs the heat of the second heating element 11 conducting to the pump casing 31.

If the impeller 44 of the heat exchanger pump 30 is rotated, a kinetic energy is applied to the liquid refrigerant filled in the pump room 42, so that the pressure of liquid refrigerant is increased within the pump room 42 owing to this kinetic energy. The pressurized liquid refrigerant is pushed out of the pump room 42 via the second connection passage 55 into the discharge port 53.

In other words, the liquid refrigerant within the pump room 42 is pressurized by the rotating impeller 44, while taking the heat from the second heating element 11. Therefore, the flow velocity of the liquid refrigerant flowing through the pump room 42 is faster, so that heat transfer from the pump casing 31 to the liquid refrigerant is made more efficiently.

The liquid refrigerant pressurized by the pump room 42 flows through the discharge port 53 via the second tube 92 into the refrigerant flow passage 22 of the first heat receiving portion 16. The liquid refrigerant absorbs the heat of the first heating element 10 conducting to the heat receiving casing 20 in the course of flowing on the refrigerant flow passage 22.

At the time when the liquid refrigerant flows into the refrigerant flow passage 22 of the first heat receiving portion 16, the temperature of the liquid refrigerant rises due to a heat receiving action in the second heat receiving portion 17. However, the flow rate of liquid refrigerant per unit time is decided so that the temperature of the liquid refrigerant led to the first heat receiving portion 16 may be lower than the temperature of the first heating element 10 conductive to the heat receiving casing 20 in the first embodiment.

As a result, a temperature difference between the liquid refrigerant and the heat receiving casing 20 is kept, and when the liquid refrigerant flows on the refrigerant flow passage 22, this liquid refrigerant can deprive the first heating element 10 of the heat conductive to the heat receiving casing 20.

The liquid refrigerant passing through the refrigerant flow passage 22 is fed from the flow outlet 24 via the third tube 93 into the inflow tank 68 of the radiator 65. The liquid refrigerant returned to the inflow tank 68 is led through the first water pipes 71 into the reserve tank 70, and then fed through the second water pipes 72 into the outflow tank 69. In this course of flow, the heat of the first and second heating elements 10 and 11 absorbed by the liquid refrigerant conducts to the first and second water pipes 71 and 72 and the fins 73.

The axial flow fan 66 of the heat radiation portion 18 starts the operation when the temperature of liquid refrigerant reaches a preset value. Thereby, the impeller 82 is rotated, and the air outside the housing 2 is sucked through the intake port 79 into the housing 2. This air becomes a cooling wind to pass between the first and second water pipes 71 and 72 and compulsorily cool the first and second water pipes 71 and 72 and the fins 73. As a result, most of the heat conducting to the first and second water pipes 71 and 72 and the fins 73 is brought away along with the flow of cooling wind.

The liquid refrigerant cooled by heat exchange with the radiator 65 is led from the outflow tank 69 via the first tube 91 into the pump room 42 of the heat exchanger pump 30. This liquid refrigerant is pressurized by rotations of the impeller 44 while taking the heat from the pump casing 31, and fed to the refrigerant flow passage 22 of the first heat receiving portion 16.

Hence, the liquid refrigerant is circulated repeatedly from the radiator 65 to the second heat receiving portion 17 to the first heat receiving portion 16, so that the heat of the first and second heating elements 10 and 11 is transferred to the radiator 65 during this circulation.

According to the first embodiment, the liquid refrigerant cooled by the radiator 65 is firstly led to the second heat receiving portion 17 containing the heat exchanger pump 30 to absorb the heat of the second heating element 11, and then led to the first heat receiving portion 16.

Therefore, the liquid refrigerant led to the second heating element 11 having a greater heating value than the first heating element 10 is not subjected to thermal influence from the first heating element 10. Hence, a temperature difference between the second heating element 11 requiring more cooling than the first heating element 10 and the liquid refrigerant is fully kept, so that the second heating element 11 can be cooled more efficiently.

Additionally, with the above constitution, the first heat receiving portion 10 and the second heat receiving portion 17 are separated from each other, and connected via the second tube 92, whereby the relative position between the first heat receiving portion 10 and the second heat receiving portion 17 can be set at will. Therefore, the first heating element 10 and the second heating element 11 can be laid out at any position on the printed circuit board 8, whereby the degree of freedom in deciding the patterning of the printed circuit board 8 is increased.

Moreover, in the first embodiment, the heat exchanger pump 30 and the radiator 65 are provided with the reserve tanks 43 and 70 having the gas-liquid separation function, respectively. Therefore, the gas components such as air bubbles permeating through the first to third tubes 91 to 93 and mixing into the liquid refrigerant can be separated and removed at two sites on the passage through which the liquid refrigerant circulates.

In particular, two reserve tanks 43 and 70 are arranged in the series positional relationship upstream of the pump room 42 of the heat exchanger pump 30. Accordingly, it is possible to surely remove the air bubbles obstructing heat transfer from the liquid refrigerant flowing into the pump room 42, and enhance the cooling efficiency of the second heating element 11 reaching the highest temperature.

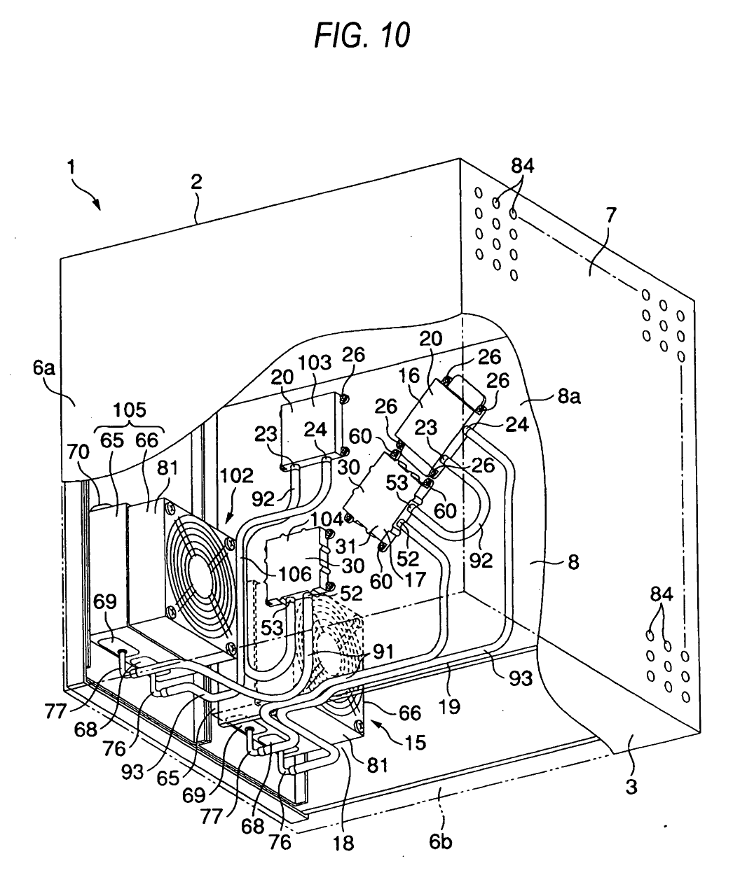

This invention is not limited to the first embodiment as described above. FIGS. 10 to 12 show a second embodiment of the invention.

In the second embodiment, a third heating element 100 and a fourth heating element 101 having a greater heating value than the third heating element 100 are mounted on the first face 8a of the printed circuit board 8. Moreover, the housing 2 accommodates another cooling device 102 of liquid cooling type for cooling the third and fourth heating elements 100 and 101.

The third and fourth heating elements 100 and 101 are electronic parts such as a semiconductor package, and located in front of the first and second heating elements 10 and 11. The fourth heating element 101 having a greater heating value than the third heating element 100 is located under the third heating element 100.

Another cooling device 102 comprises a first heat receiving portion 103, a second heat receiving portion 104, a heat radiation portion 105 and a circulation passage 106. The first heat receiving portion 103, the second heat receiving portion 104, the heat radiation portion 105 and the circulation passage 106 correspond to the first heat receiving portion 16, the second heat receiving portion 17, the heat radiation portion 18 and the circulation passage 19 of the first embodiment, respectively. The constitution thereof is fundamentally the same as in the first embodiment.

Accordingly, the first heat receiving portion 103, the second heat receiving portion 104, the heat radiation portion 105 and the circulation passage 106 are designated by the same reference numerals as in the first embodiment, and not described here.

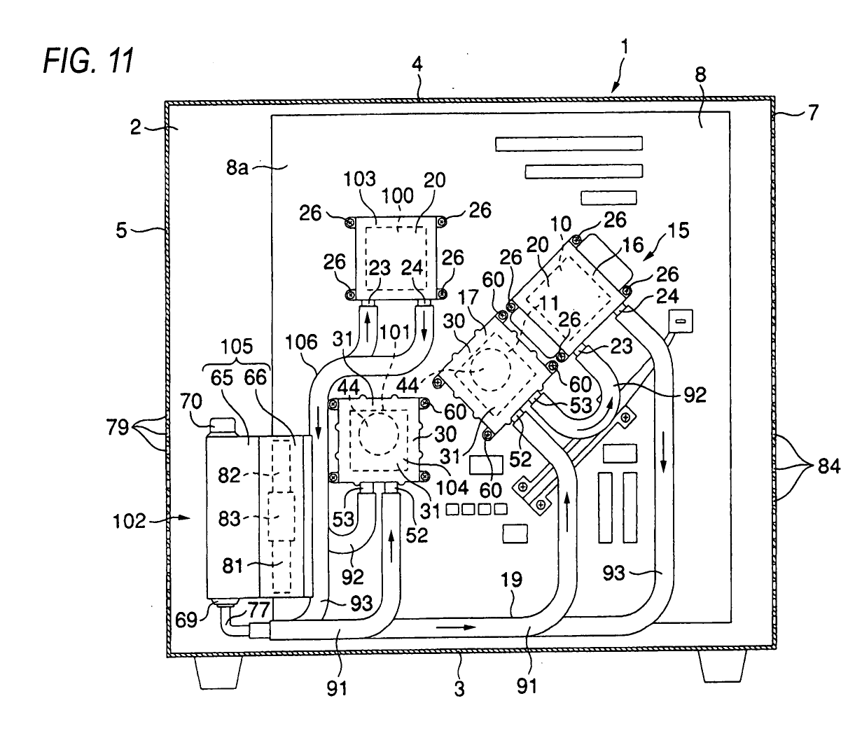

As shown in FIG. 11, the first heat receiving portion 103 is held in the printed circuit board 8 to cover the third heating element 100, and thermally connected to the third heating element 100. Likewise, the second heat receiving portion 104 containing the heat exchanger pump 30 is held in the printed circuit board 8 to cover the fourth heating element 101, and thermally connected to the fourth heating element 101.

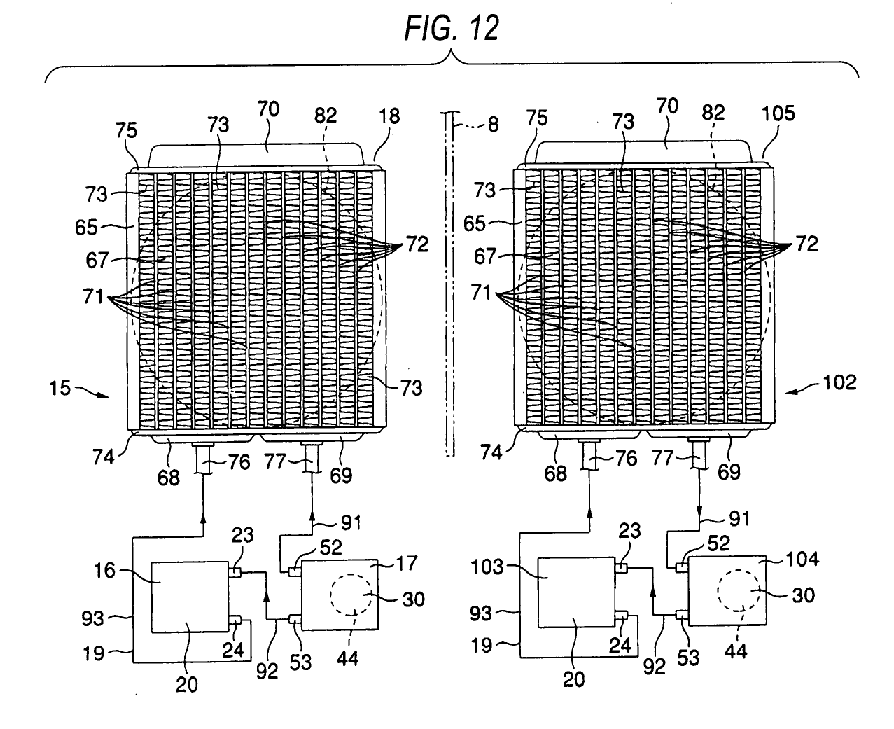

The heat radiation portion 105 is disposed on the bottom portion at the front end of the housing 2. As shown in FIG. 12, in the second embodiment, two heat radiation portions 18 and 105 are arranged in the width direction of the housing 2, with the front end part of the printed circuit board 8 being fitted between the heat radiation portions 18 and 105.

The liquid refrigerant cooled by the radiator 65 of the heat radiation portion 105 is firstly led to the heat exchanger pump 30 of the second heat receiving portion 104 to absorb the heat of the fourth heating element 101, and then led into the first heat receiving portion 103. The liquid refrigerant led to the first heat receiving portion 103 absorbs the heat of the third heating element 100, and then returns to the radiator 65 for cooling by heat exchange with the cooling wind.

Therefore, in another cooling device 102, the liquid refrigerant led to the fourth heating element 101 reaching higher temperature than the third heating element 100 is not subjected to thermal influence of the third heating element 100. Accordingly, a temperature difference between the fourth heating element 101 having a greater heating value and the liquid refrigerant is fully kept, so that the fourth heating element 101 can be cooled efficiently.

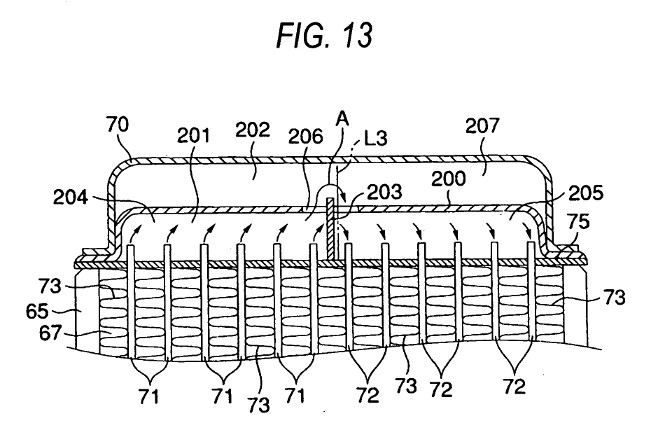

FIG. 13 shows a third embodiment of the invention.

This third embodiment is different from the first embodiment in the internal structure of the reserve tank 70 for the radiator 65. The other constitution of the radiator 65 is the same as in the first embodiment.

As shown in FIG. 13, the inside of the reserve tank 70 is partitioned into a first chamber 201 and a second chamber 202 by a baffle plate 200. The baffle plate 200 is soldered to the upper plate 75 of the radiator 65, together with the reserve tank 70.

The upper plate 75 defines the first chamber 201 in cooperation with the baffle plate 200. A partition plate 203 as gas-liquid separation section is fixed to the upper plate 75. The partition plate 203 partitions the first chamber 201 into a refrigerant inflow area 204 and a refrigerant outflow area 205.

The upper ends of the first water pipes 71 of the radiator 65 are opened into the refrigerant inflow area 204. The upper ends of the first water pipes 71 are located below the level of the liquid refrigerant reserved in the refrigerant inflow area 204. The upper ends of the second water pipes 72 of the radiator 65 are opened into the refrigerant outflow area 205. The upper ends of the second water pipes 72 are located below the level of the liquid refrigerant reserved in the refrigerant outflow area 205.

The baffle plate 200 has an opening portion 206 at the position corresponding to the partition plate 203. The upper end of the partition plate 203 penetrates through the opening portion 206 and slightly projects into the second chamber 202. Therefore, the refrigerant inflow area 204 of the first chamber 201 leads via the opening portion 206 and the second chamber 202 to the refrigerant outflow area 205.

The liquid refrigerant returning from the first heat receiving portion 16 to the radiator 65 is discharged from the inflow tank 68 via the first water pipes 71 to the refrigerant inflow area 204 of the reserve tank 70. The liquid refrigerant within the refrigerant inflow area 204 enters the opening portion 206, and overflows the partition plate 203 to flow into the refrigerant outflow area 205, as indicated by the arrow A in FIG. 13.

With this constitution, when the liquid refrigerant reserved in the refrigerant inflow area 204 overflows the partition plate 203, the gas components such as air bubbles contained in this liquid refrigerant are separated from the liquid refrigerant, and released into the second chamber 202. Therefore, the second chamber 202 of the radiator 65 functions as the air reservoir 207.

When the radiator 65 is installed in a transverse attitude so that the first and second water pipes 71 and 72 may be horizontal, the attitude of the radiator 65 is defined so that the second pipes 72 may be located under the first water pipes 71. Thereby, the end portions of the second water pipes 72 are located below the level L3 of the liquid refrigerant within the reserve tank 70, and the partition plate 203 is located above the level L3, as indicated by the two-dot chain line.

Therefore, the liquid refrigerant discharged from the first water pipes 71 into the refrigerant inflow area 204 flows from the opening portion 206 via the second chamber 202 into the refrigerant outflow area 205, with the partition plate 203 as a guide.

Hence, whether the radiator 65 is installed longitudinally or transversely, it is possible to surely remove the gas components obstructing the heat transfer from the liquid refrigerant returning to the reserve tank 70, whereby the cooling efficiency of the second heating element 11 reaching the highest temperature can be enhanced.

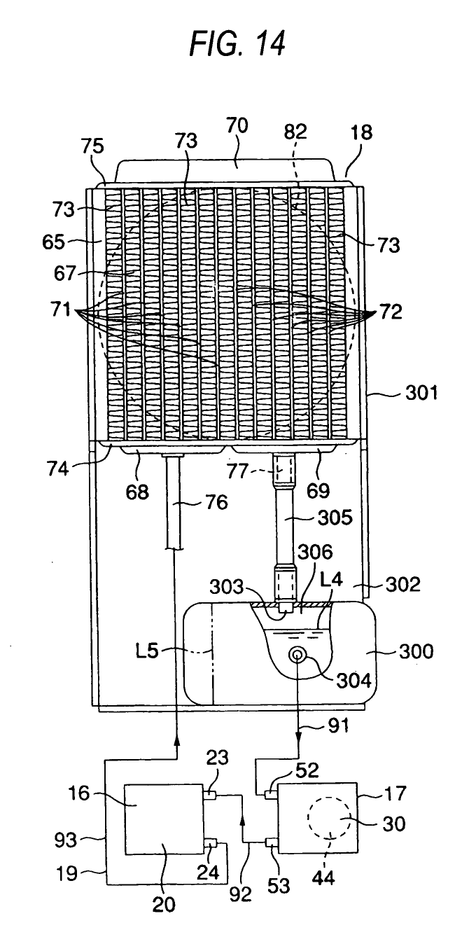

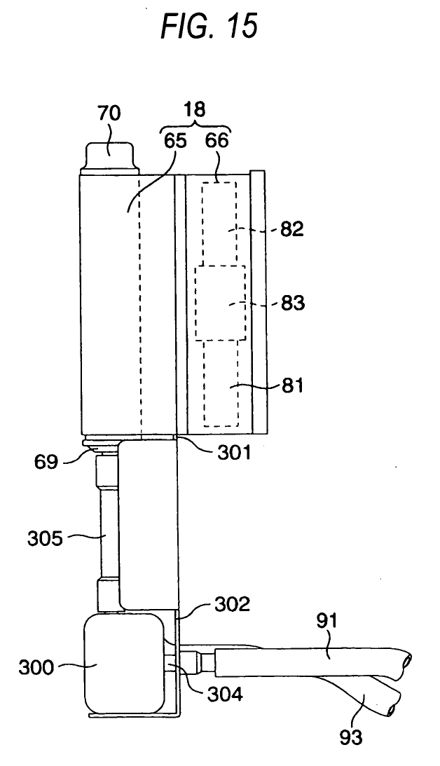

FIGS. 14 and 15 show a fourth embodiment of the invention.

In this fourth embodiment, a dedicated reserve tank 300 is installed in the heat radiation portion 18 of the cooling device 15. The other constitution of the heat radiation portion 18 is fundamentally the same as in the first embodiment. Therefore, in the fourth embodiment, the same components are designated by the same reference numerals as in the first embodiment, and not described here.

As shown in FIGS. 14 and 15, the heat radiation portion 18 has a frame 301 integrally connecting the radiator 65 and the axial flow fan 66. The frame 301 has a tank supporting portion 302 projecting under the radiator 65. The reserve tank 300 is held at the lower end of the tank supporting portion 302.

The reserve tank 300 is like an oblong box having a quite greater content volume than the reserve tank 70 attached with the radiator 65. The reserve tank 300 has a refrigerant flow inlet 303 and a refrigerant flow outlet 304.

The refrigerant flow inlet 303 is provided in the almost central part on the upper face of the reserve tank 300. The refrigerant flow inlet 303 is connected via a connection tube 305 to the refrigerant outlet 77 of the radiator 65, and located above the level L4 of liquid refrigerant reserved in the reserve tank 300.

The refrigerant flow outlet 304 is provided in the almost central part on the side face of the reserve tank 300 to be located under the refrigerant flow inlet 303. The refrigerant flow outlet 304 is connected via the first tube 91 to the suction opening 52 of the heat exchanger pump 30.

Moreover, the refrigerant flow outlet 304 is located below the level L4 of liquid refrigerant within the reserve tank 300. Therefore, an air reservoir 306 is formed between the upper face of the reserve tank 300 and the level L4 of the liquid refrigerant.

With this constitution, the liquid refrigerant cooled by the radiator 65 flows via the refrigerant flow inlet 303 into the reserve tank 300, upstream of the heat exchanger pump 30 along the flow direction of liquid refrigerant. The refrigerant flow outlet 304 of the reserve tank 300 is located below the level L4 of liquid refrigerant reserved in the reserve tank 300.

Therefore, even if the gas components not separated in the reserve tank 70 of the radiator 65 are contained in the liquid refrigerant, the gas components are separated and removed from the liquid refrigerant in the course of flowing into the reserve tank 300, and released into the air reservoir 306.

Accordingly, the reserve tank 300 of fourth embodiment also serves as gas-liquid separation section for separating the gas components from the liquid refrigerant flowing from the radiator 65 to the heat exchanger pump 30.

Moreover, according to the fourth embodiment, three reserve tanks 70, 300 and 43 having a gas-liquid separation function are interposed in series on the flow passage of liquid refrigerant leading from the radiator 65 to the pump room 42 of the heat exchanger pump 30. Therefore, it is possible to surely remove the air bubbles obstructing heat transfer from the liquid refrigerant receiving the heat of the second heating element 11 in the pump room 42, and enhance the cooling efficiency of the second heating element 11 reaching the highest temperature.

Even when the radiator 65 is installed in the transverse attitude, the refrigerant flow outlet 304 of the reserve tank 300 is located below the level L5 of liquid refrigerant as indicated by the two-dot chain line in FIG. 14 and the refrigerant flow inlet 303. Accordingly, the gas components contained in the liquid refrigerant are separated and removed from the liquid refrigerant in the course of flowing into the reserve tank 300.

Hence, whether the radiator 65 is installed longitudinally or transversely, it is possible to surely remove the air bubbles obstructing heat transfer from the liquid refrigerant.

This invention is not limited to the above embodiments, but various modifications may be made without departing from the scope or spirit of the invention.

For example, the first heating element and the first heat receiving portion are provided singly in the embodiments, but two or more first heat receiving portions may be thermally connected to two or more first heating elements, and the refrigerant flow passages of the first heat receiving portions may be connected in series or in parallel.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A cooling device comprising:
a first heat receiving portion that is configured to be thermally connected to a first heating element;
a second heat receiving portion that is configured to be thermally connected to a second heating element having a greater heating value than the first heating element, the second heat receiving portion having a pump that pressurizes and feeds a liquid refrigerant;
a heat radiation portion that radiates the heat received by the first and second heating elements; and
a circulation passage that circulates a liquid refrigerant around the first heat receiving portion, the second heat receiving portion, and the heat radiation portion,
wherein the second heat receiving portion is located at a position upstream with respect to the first heat receiving portion in a flow direction of the liquid refrigerant and downstream with respect to the heat radiation portion in the flow direction.

2. The cooling device according to claim 1, wherein the first heat receiving portion, the second heat receiving portion and the heat radiation portion are connected in series by the circulation passage.

3. The cooling device according to claim 1, wherein the circulation passage has a tube that is configured to be thermally connected between first heat receiving portion and the second heat receiving portion.

4. The cooling device according to claim 1, wherein the each of second heat receiving portion and the heat radiation portion has a reserve tank that reserves the liquid refrigerant.

5. The cooling device according to claim 4, wherein the reserve tank has a gas-liquid separation section that separates gas component contained in the liquid refrigerant.

6. The cooling device according to claim 1, wherein the circulation passage has a first reserve tank that reserves the liquid refrigerant at a portion between the heat radiation portion and the second heat receiving portion, and the first reserve tank has gas-liquid separation section that separates gas component contained in the liquid refrigerant.

7. The cooling device according to claim 6, wherein the second heat receiving portion has a second reserve tank, and the heat radiation portion has a third reserve tank, and the first, second, and third reserve tanks for reserving the liquid refrigerant have gas-liquid separation section which separate the gas components contained in the liquid refrigerant.

8. The cooling device according to claim 6, wherein the heat radiation portion have a radiator for cooling the liquid refrigerant, a fan for blowing cooling airstream to the radiator, the radiator, and a frame for integrally supporting the fan and a third reserve tank.

9. An electronic apparatus comprising:
a housing that is configured to accommodating a first heating element and a second heating element having a greater heating value than the first heating element, the second heat receiving portion having a pump that pressurizes and feeds a liquid refrigerant;
a cooling device that is accommodated within the housing, for cooling the first and second heating elements employing a liquid refrigerant;
wherein the cooling device comprises:
a first heat receiving portion that is configured to be thermally connected to the first heating element;
a second heat receiving portion that is configured to be thermally connected to the second heating element;
a heat radiation portion that radiates the heat of the first and second heating elements; and
a circulation passage that circulates the liquid refrigerant around the first heat receiving portion, the second heat receiving portion, and the heat radiation portion,
wherein the second heat receiving portion is located at a position upstream with respect to the first heat receiving portion in a flow direction of the liquid refrigerant and downstream with respect to the heat radiation portion in the flow direction.

10. The electronic apparatus according to claim 9, wherein the housing that is configured to accommodates a circuit board on which the first and second heating elements are mounted, and the first and second heat receiving portions are individually attached to the circuit board.
